(19) United States
(12) Patent Application Publication
(10) Pub. No.: US 2010/0071741 A1
(43) Pub. Date: Mar. 25, 2010

(54) THERMOELECTRIC MATERIAL INCLUDING A FILLED SKUTTERUDITE CRYSTAL STRUCTURE

(75) Inventors: Jihui Yang, Lakeshore (CA); Xun Shi, Troy, MI (US); Shengqiang Bai, Shanghai (CN); Wenqing Zhang, Shanghai (CN); Lidong Chen, Shanghai (CN)

Correspondence Address: Julia Church Dierker;Dierker & Associates, P.C., 3331 W. Big Beaver Road, Suite 109, Troy, MI, 48084-2813, US

(73) Assignees: GM GLOBAL TECHNOLOGY OPERATIONS, INC., DETROIT, MI (US); SHANGHAI INSTITUTE OF CERAMICS, CHINESE ACADEMY OF SCIENCES, SHANGHAI (CN)

(21) Appl. No.: 12/434,299

(22) Filed: May 1, 2009

Related U.S. Application Data
(63) Continuation-in-part of application No. 12/396,875, filed on Mar. 3, 2009.
(60) Provisional application No. 61/036,715, filed on Mar. 14, 2008.

(51) Int. Cl. H01L 35/20; H01L 35/12

(52) U.S. Cl. 136/240; 136/236.1

(57) ABSTRACT

A thermoelectric material includes a filled skutterudite crystal structure having the formula G_{y}M₄X₁₂, where i) G includes at least two rare earth elements and an alkaline earth element, ii) M is cobalt, rhodium, or iridium, and iii) X is antimony, phosphorus, or arsenic. The subscript “y” refers to a crystal structure filling fraction ranging from about 0.001 to about 0.5.

### CROSS-REFERENCE TO RELATED APPLICATIONS

The instant application is a continuation-in-part of co-pending U.S. application Ser. No. 12/396,875 filed Mar. 3, 2009, which claims the benefit of U.S. Provisional Application Ser. No. 61/036,715 filed Mar. 14, 2008, the contents of which are incorporated herein by reference.

### STATEMENT REGARDING FEDERALLY SPONSORED RESEARCH OR DEVELOPMENT

This invention was made in the course of research and/or development supported by the U.S. Department of Energy, under Government Contract No. DE-FC26-04NT42278. The U.S. government has certain rights in the invention.

### TECHNICAL FIELD

The present disclosure relates generally to thermoelectric materials, and more particularly to a thermoelectric material including a filled skutterudite crystal structure.

### BACKGROUND

Thermoelectric materials including filled skutterudite crystal structures may be used at least for power generation applications. Such materials generally include a binary skutterudite crystal structure having guest atom(s) introduced into void(s) present in the crystal structure. In an example, the binary skutterudite structure may be a cobalt arsenide material having the general formula CoAs₃, a cobalt antimony material having the general formula Co₄Sb₁₂, or the like. In some instances, the binary skutterudite structure may include varying amounts of nickel and iron in place of the cobalt.

### SUMMARY

A thermoelectric material includes a filled skutterudite crystal structure having the formula G_{y}M₄X₁₂, where G includes at least i) a rare earth element, ii) an other rare earth element, and iii) an alkaline earth element, where M is selected from cobalt, rhodium, and iridium, and X is selected from antimony, phosphorus, and arsenic. The subscript “y” refers to a crystal structure filling fraction ranging from about 0.001 to about 0.5.

### BRIEF DESCRIPTION OF THE DRAWINGS

Features and advantages of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a schematic perspective representation of an example of a skutterudite body-centered-cubic crystal structure having the formula G_{y}M₄X₁₂;

FIG. 2 is a graph showing the thermoelectric figure of merit, ZT, profiles for several examples of some known thermoelectric materials over a temperature range of 0K to 1400K;

FIG. 3 is a graph showing the thermoelectric figure of merit, ZT, profiles for an example of a multiple element filled skutterudite type thermoelectric material, as well as examples of the some known thermoelectric materials over a temperature range of 0K to 1400K;

FIG. 4 is a graph showing the thermoelectric figure of merit, ZT, profiles of other examples of a multiple element filled skutterudite type thermoelectric material, the example of the multiple element filled skutterudite type thermoelectric material depicted in FIG. 3, as well as some examples of known thermoelectric materials over a temperature range of 0K to 1400K;

FIG. 5 is a graph showing thermal conductivity (κ_{L}) versus crystal structure filling fraction for various examples of multiple element filled skutterudite type thermoelectric materials, as well as examples of single element filled skutterudite type thermoelectric materials; and

FIG. 6 schematically depicts a thermoelectric device including a thermoelectric power generator using a filled skutterudite thermoelectric material.

### DETAILED DESCRIPTION

The efficiency of a thermoelectric material is often characterized by a thermoelectric figure of merit, ZT. The figure of merit, ZT, is a dimensionless product and is defined by the formula:

$$ZT = \frac{{S}^{2} T}{ρκ} = \frac{{S}^{2} T}{ρ ( {κ}_{L} + {κ}_{e} )} \qquad ( Eqn . 1 )$$

where S, ρ, κ, κ_{L}, κₑ, and T are the Seebeck coefficient (or thermopower), electrical resistivity, total thermal conductivity, lattice thermal conductivity, electronic thermal conductivity, and absolute temperature, respectively. An efficient thermoelectric material generally possesses a combination of a high Seebeck coefficient, a low electrical resistivity, and a low thermal conductivity, and, therefore, may be classified as a material having a suitably high figure of merit, ZT. To drive the figure of merit upwards, the thermoelectric material should be formed in a manner sufficient to i) increase the Seebeck coefficient, ii) decrease the electrical resistivity, and/or iii) decrease the thermal conductivity.

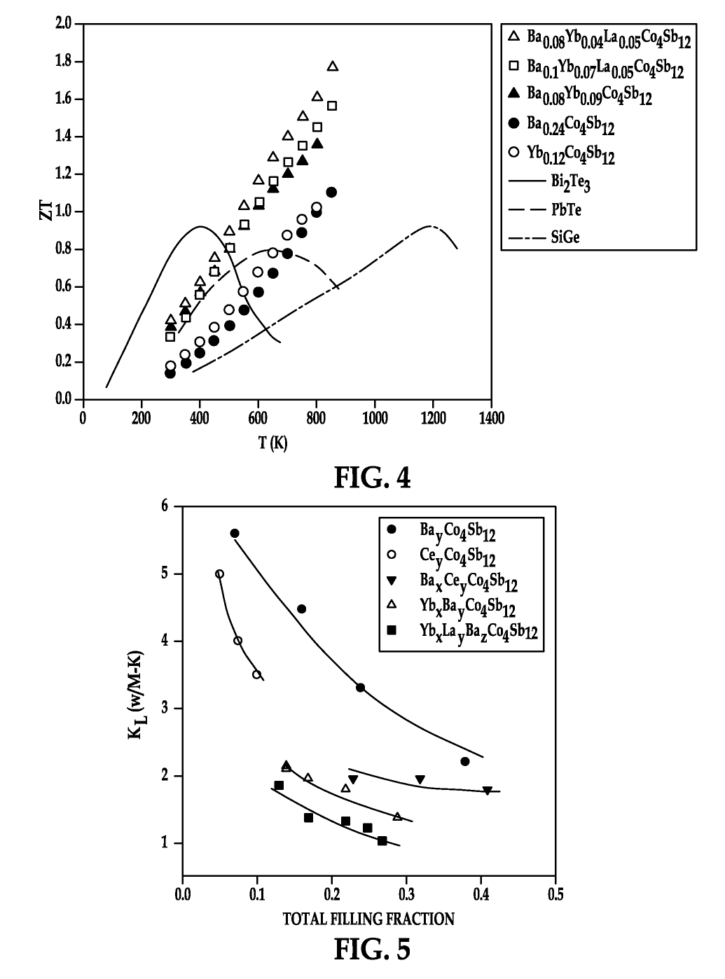

Filled skutterudite structures have been discovered as being a suitable thermoelectric material that exhibits a lower lattice thermal conductivity, and thus a higher figure of merit, ZT. Such a material may include a single element filled skutterudite material such as, e.g., Ba_{0.24}Co₄Sb₁₂. This example of the single element filled skutterudite material exhibits a figure of merit, ZT, of about 1.1 at a moderate temperature (e.g., about 850K), as shown in FIG. 4. Such a ZT value is significantly higher than other known thermoelectric materials tested (as described hereinbelow in conjunction with the Examples) or reported in literature thus far.

The inventors of the instant application have discovered that skutterudite thermoelectric materials filled with multiple elements further reduce the lattice thermal conductivity, thereby improving the figure of merit, ZT, beyond what has been achieved with the single element filled structure noted above and, it is believed, for any thermoelectric materials reported thus far. In some examples of the instant disclosure, the skutterudite structure may be filled with at least two elements, one of which is a rare earth element. In other examples, the skutterudite structure may be filled with at least three elements, two of which are rare earth elements. Without being bound to any theory, it is believed that the lattice thermal conductivity of a rare earth element filled skutterudite structure tends to significantly reduce over a wide temperature range, as compared with binary skutterudite structures or skutterudite structures filled with an element other than a rare earth element. This reduced lattice thermal conductivity may be due, at least in part, to the substantially heavy rare earth atoms that rattle inside the interstitial voids of the skutterudite structure, thereby scattering heat-carrying low frequency phonons therein. Phonons having frequencies that are close to the resonance frequencies of the rattling element(s) tend to interact with local modes induced by the rattling element(s) and drive the lattice thermal conductivity down.

It is further believed that the lattice thermal conductivity may also be reduced by introducing guest atoms having different resonance frequencies in the skutterudite structure. As shown in FIG. 5, multiple element filled skutterudite materials tend to exhibit lower thermal conductivities than other skutterudite materials filled with a single guest atoms (e.g., a single element filled skutterudite structure).

Accordingly, examples of the multiple element filled skutterudite structure, as disclosed herein, have at least one rare earth element as a guest atom. In many instances, each guest atom is also independently selected to have different phonon resonance frequencies. In an example, the phonon resonance frequencies vary by about 10 cm⁻¹ or more. In another example, the phonon resonance frequencies vary by about 15 cm⁻¹ or more. The examples of the multiple element filled skutterudite thermoelectric material have an average figure of merit, ZT, of at least about 1.4 and, in some cases, even up to about 2.0 at a temperature of about 800K.

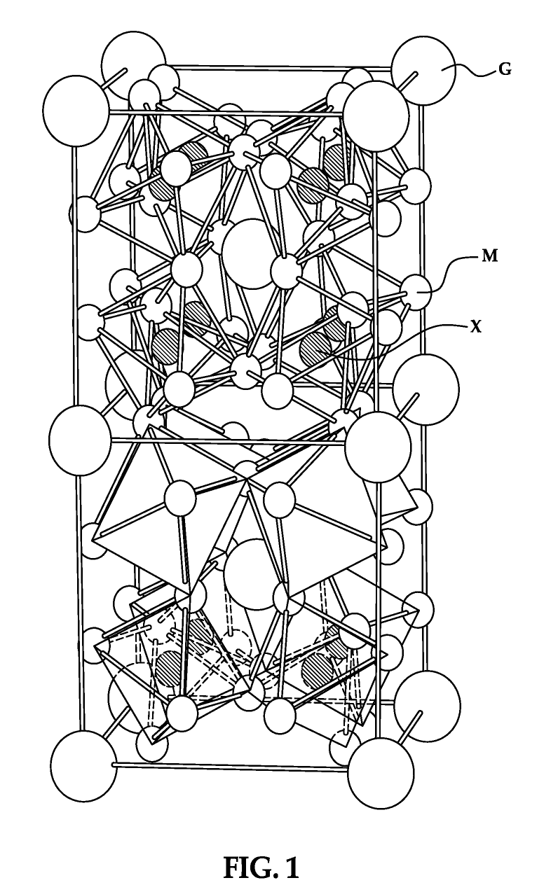

The examples of the multiple element filled skutterudite thermoelectric material generally includes a skutterudite body-center-cubic structure (as shown in FIG. 1) having a space group Im3. The skutterudite structure further includes several voids interstitially defined therein, where such voids may be filled with the guest atoms (also often referred to as “fillers”). The multiple element filled skutterudite structure generally has the formula of G_{y}M₄X₁₂; where M is a metal selected from cobalt, rhodium, and iridium; X is an element selected from the pnictogen group, such as antimony, phosphorus, and arsenic; G is at least two fillers or guest atoms; and the subscript “y” is a crystal structure filling fraction of the fillers or guest atoms, G. In a non-limiting example, y ranges from about 0.001 to about 0.5.

The multiple element filled skutterudite material may be formed by inserting the guest atoms, G, interstitially into one or more suitably large voids in the crystal structure of a binary skutterudite compound (shown in FIG. 1). In all of the examples described hereinbelow, each guest atom, G, used to fill the voids in the skutterudite structure has a different chemical nature. For example, the skutterudite crystal structure may include at least two filling elements, G, which include i) a rare earth element, and ii) an alkaline earth element. In another example, the two filling elements, G, of the skutterudite structure include i) a rare earth element, and ii) an alkali metal element. Either of the foregoing examples may also be doped with one or more thermoelectric n-type or p-type doping materials. Non-limiting examples of suitable n-type dopants include nickel, palladium, or platinum. Such n-type dopants may be doped on the M element in the skutterudite material. Other non-limiting examples of suitable n-type dopants include selenium and tellurium, which may be doped on the X element in the skutterudite material. Non-limiting examples of suitable p-type dopants include iron rubidium and osmium, where such p-type dopants may be doped on the M element. Other non-limiting examples of a p-type dopant include germanium or tin, where such dopants may be doped on the X element.

Non-limiting examples of rare earth elements for at least one of the guest atoms G include elements selected from the lanthanide and actinide series of the periodic table of chemical elements. Such elements may include, but are not limited to, lanthanum, cerium, praseodymium, neodymium, promethium, samarium, europium, gadolinium, terbium, dysprosium, holmium, erbium, thulium, ytterbium, lutetium, actinium, thorium, protactinium, uranium, neptunium, plutonium, americium, curium, berkelium, californium, einsteinium, fermium, mendelevium, nobelium, and lawrencium.

Additionally, non-limiting examples of alkaline earth elements for at least one of the guest atoms G include beryllium, magnesium, calcium, strontium, barium, and radium.

Furthermore, non-limiting examples of alkaline metal elements for at least one of the guest atoms G include lithium, sodium, potassium, rubidium, cesium, and francium.

Yet another example of a multiple filled skutterudite material may generally be identified by the formula AₓD_{y}E_{z}M₄X₁₂, where A, D, and E are guest atoms G of different chemical natures. Such a thermoelectric material may be referred to as a triple element filled skutterudite material. In this example, A is a rare earth element, D is an alkaline earth element, and E is an alkali metal element, where the subscripts “x,” “y,” and “z” are crystal structure filling fractions of the elements A, D, and E, respectively. In a non-limiting example, “x,” “y,” and “z” each range from about 0.001 to about 0.2. Further, M is a metal selected from cobalt, rhodium, and iridium. In some instances, M may be doped with varying amounts of, e.g., i) nickel, palladium, and platinum, and/or ii) iron, rubidium, and osmium. Also, X is selected from a member of the pnictogen group, such as, e.g., phosphorus, arsenic, and/or antimony. In some instances, X may also be doped with varying amounts of, e.g., i) germanium and tin, and/or ii) selenium and tellurium. Such a triple element filled skutterudite material may also be doped with other n-type or p-type thermoelectric materials for use in a variety of other applications.

Another example of a multiple element filled skutterudite type thermoelectric material is also designated by the formula G_{y}M₄X₁₂, where G includes at least i) a rare earth element, ii) another rare earth element, and iii) an alkaline earth element. In this example, M is also a metal selected from cobalt, rhodium, and iridium. Furthermore, X is a member of the pnictogen group, such as antimony, phosphorus, and arsenic. The subscript “y” refers to the crystal structure filling fraction of the guest atoms, which ranges from about 0.01 to about 0.5. In this example, the first rare earth element is different from the second rare earth element. In many cases, the first rare earth element is ytterbium and the other/second rare earth element is selected from a rare earth element other than ytterbium (non-limiting examples of which include lanthanum, cerium, praseodymium, neodymium, promethium, samarium, europium, gadolinium, terbium, dysprosium, holmium, erbium, thulium, lutetium, actinium, thorium, protactinium, uranium, neptunium, plutonium, americium, curium, berkelium, californium, einsteinium, fermium, mendelevium, nobelium, and lawrencium). The multiple filled skutterudite thermoelectric material of the instant example may be designated by the formula RₓA_{y}B_{z}M₄X₁₂, where R is a rare earth element, A is a rare earth element other than R, and B is an alkaline earth element. In a non-limiting example, R is ytterbium and A is a rare earth element other than ytterbium. The subscripts “x,” “y,” and “z” are crystal structure filling fractions of R, A, and B, respectively, where each of “x,” “y,” and “z” ranges from about 0.01 to about 0.2. The elements A and B are also selected so that R, A and B independently have different phonon resonance frequencies. In a non-limiting example, the phonon resonance frequencies of A and B differs by about 15 cm⁻¹. One non-limiting example of such a multiple element filled skutterudite type thermoelectric material has the formula Yb_{0.07}La_{0.05} Ba_{0.10}Co₄Sb₁₂.

Still another example of the multiple element filled skutterudite thermoelectric material is designated by the formula R_{w}AₓB_{y}C_{z}M₄X₁₂, where R is a rare earth element, A is a rare earth element other than R, B is an alkaline earth element, and C is an alkali metal. In a non-limiting example, R is ytterbium and A is a rare earth element other than ytterbium. In the foregoing example of the multiple element filled skutterudite thermoelectric material, M is a metal selected from cobalt, rhodium, and iridium, and X is a member of the pnictogen group such as, e.g., antimony, phosphorus, or arsenic. Additionally, the subscripts “w,” “x,” “y,” and “z” are crystal structure filling fractions of R, A, B, and C, respectively, where such filling fractions range from about 0.01 to about 0.2. An example of such a thermoelectric material includes a binary skutterudite structure having voids filled with ytterbium, lanthanium, barium, and one of sodium or potassium. Again, each of the R, A, B, and C has a different phonon resonance frequency. A non-limiting example of such a multiple element filled skutterudite structure has the formula Yb_{w}LaₓBa_{y}Na_{z}Co₄Sb₁₂, where the subscripts “w,” “x,” “y,” and “z” ranges from about 0.01 to about 0.2. Another non-limiting example of the multiple element filled skutterudite structure has the formula Yb_{w}LaₓBa_{y}K_{z}Co₄Sb₁₂, where the subscripts “w,” “x,” “y,” and “z” ranges from about 0.01 to about 0.2.

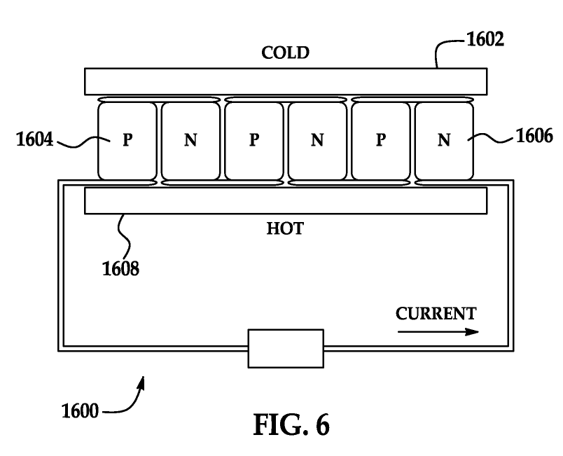

The several examples of the filled skutterudite thermoelectric material disclosed hereinabove may be used to make a variety of thermoelectric devices, an example of which is shown in FIG. 6. FIG. 6 depicts a thermoelectric power generator 1600 including an n-type multiple filled element skutterudite thermoelectric material (identified by reference numeral 1606) and a p-type multiple filled element skutterudite thermoelectric material (identified by reference numeral 1604). The power generator 1600 includes a hot side (identified by a plate 1608), which is in contact with a heat source of high temperature Tₕ. The power generator 1600 further includes a cold side (identified by a plate 1602), which is in contact with a heat sink of low temperature T_{c}, where T_{c} is lower than Tₕ. A temperature gradient formed between the plate 1608 (i.e., the hot side) and the plate 1602 (i.e., the cold side) causes electrons in the thermoelectric materials 1604, 1606 to move away from the plate 1608 at the hot side and towards the plate 1602 at the cold side, thereby generating an electric current. Power generation may, for example, be increased by increasing the temperature difference between the hot plate 1608 and the cold plate 1602 and by using the examples of the multiple element filled skutterudite materials disclosed hereinabove, where such materials exhibit the desirably higher figure of merit, ZT, value.

To further illustrate example(s) of the present disclosure, various examples are given herein. It is to be understood that these are provided for illustrative purposes and are not to be construed as limiting the scope of the disclosed example(s).

### EXAMPLES

### Example 1

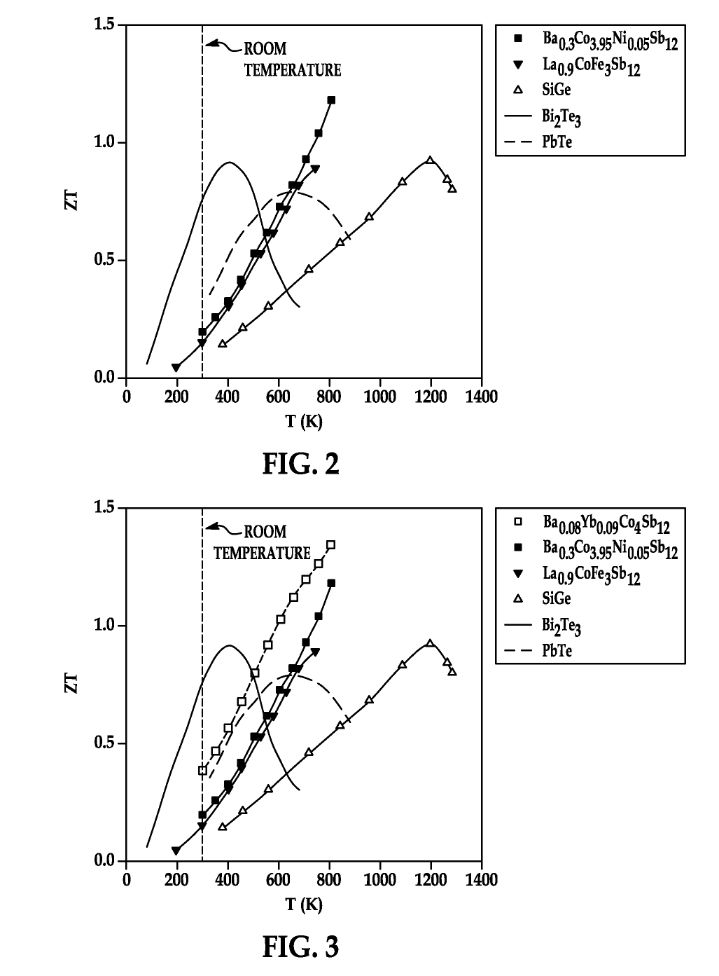

Data for several known thermoelectric materials were retrieved from literature to determine the materials' respective figure of merit, ZT, values. Such materials include single-filled skutterudite structures (Ba_{0.3}CO_{3.95}Ni_{0.05}Sb₁₂ and La_{0.9}CoFe₃Sb₁₂), and alloys including Bi₂Te₃, PbTe, and SiGe. The thermoelectric figure of merit, ZT, for temperatures ranging from about 0K to about 1400K for these thermoelectric materials are shown in FIGS. 2 and 3.

Further, a sample of a multiple-filled skutterudite thermoelectric material was prepared and tested to determine its figure of merit, ZT, value. This sample was a multiple-filled skutterudite structure having the chemical formula Ba_{0.08}Yb_{0.09}Co₄Sb₁₂. The sample was prepared according to the method described in L. D. Chen, et al., J. Appl. Phys. 90, 1864 (2001), which is herein incorporated by reference in its entirety.

Thermal and electrical transport properties of the prepared sample were measured at temperatures ranging from about 0K to about 900K. For example, thermal diffusivity measurements were made using an Anter Flashline™ FL5000 laser flash system equipped with a six-sample carousel and an aluminum block furnace. The sample was formed into discs that were about 12.6 mm in diameter and about 1 mm in thickness for use in the Anter Flashline™ FL5000 laser flash system. Also, data related to the heating and cooling properties of the same were measured using a Netzsch Pegasus® 404 C high temperature differential scanning calorimeter (DSC). The heating and cooling data were then used to calculate the specific heat (C_{ρ}) of the sample following an ASTM standard procedure, such as ASTM Standard E1269, “Standard Test Method for Determining Specific Heat Capacity by Differential Scanning Calorimetry,” ASTM International, West Conshohocken, Pa., 2005, which is herein incorporated by reference in its entirety.

The thermal conductivity (κ) of the sample was calculated using the equation κ=α×D×C_{ρ}, where α is the thermal diffusivity, D is the mass density, and C_{ρ} is the specific heat. The thermal resistivity (ρ) and the Seebeck coefficient (S) of the sample were then measured using an ULVAC ZEM-3 system. The sample was cut into 2 mm×2 mm×11 mm parallelepipeds in order to use the ULVAC ZEM-3 system.

The figure of merit, ZT, was calculated using the equation

$$ZT = \frac{{S}^{2} T}{ρκ} = \frac{{S}^{2} T}{ρ ( {κ}_{L} + {κ}_{e} )} ,$$

where S is the Seebeck coefficient, T is the temperature, ρ is the thermal resistivity, and κ is the thermal conductivity. The figure of merit, ZT, over the temperature range of 0K to 1400K of the double-filled skutterudite type thermoelectric material (Ba_{0.08}Yb_{0.09}Co₄Sb₁₂) is shown in FIG. 3.

As shown in FIGS. 2 and 3, the figure of merit, ZT, for the example of the double-filled skutterudite material at a temperature within a range of about 600K to about 900K is significantly higher than that of the known materials.

### Example 2

Data for several known thermoelectric materials were retrieved from literature to determine the materials' respective figure of merit, ZT, values. Such materials include single-filled skutterudite structures such as Ba_{0.24}Co₄Sb₁₂ and Yb_{0.12}Co₄Sb₁₂, and alloys such as Bi₂Te₃, PbTe, and SiGe. The thermoelectric figure of merit, ZT, for temperatures ranging from about 0K to about 1400K for these thermoelectric materials are shown in FIG. 4.

An example of a double element filled skutterudite material (Ba_{0.08}Yb_{0.09}Co₄Sb₁₂), and two examples of a triple element filled skutterudite material (Ba_{0.08}Yb_{0.04}La_{0.05}Co₄Sb₁₂ and Ba_{0.01}Yb_{0.07}La_{0.05}Co₄Sb₁₂) were prepared according to the same preparation method as the double element filled thermoelectric material prepared above for Example 1.

The thermoelectric figure of merit, ZT, for temperatures ranging from about 0K to about 1400K for the prepared materials were calculated according to the same procedure described above for Example 1 and were plotted on the graph depicted in FIG. 4. As shown in FIG. 4, the figure of merit, ZT, for the examples of the triple element filled materials ranges from about 1.2 to about 1.8 at a temperature ranging from about 600K to about 900K, which is higher than that of both i) the known materials, and ii) the double element filled material.

While several embodiments have been described in detail, it will be apparent to those skilled in the art that the disclosed embodiments may be modified. Therefore, the foregoing description is to be considered exemplary rather than limiting.

1. A thermoelectric material comprising a filled skutterudite crystal structure having the formula G_{y}M₄X₁₂, wherein:
G includes at least i) a rare earth element, ii) an other rare earth element, and iii) an alkaline earth element;
M is selected from the group consisting of cobalt, rhodium, and iridium;
X is selected from the group consisting of antimony, phosphorus, and arsenic; and
y is a crystal structure filling fraction ranging from about 0.001 to about 0.5.

2. The thermoelectric material as defined in claim 1 wherein the rare earth element is different from the other rare earth element.

3. A thermoelectric material comprising a filled skutterudite crystal structure having the formula RₓA_{y}B_{z}M₄X₁₂, wherein:
R is a rare earth element;
A is a rare earth element other than R;
B is an alkaline earth element;
M is selected from the group consisting of cobalt, rhodium, and iridium;
X is selected from the group consisting of antimony, phosphorus, and arsenic; and
x, y, and z are crystal structure filling fractions ranging from about 0.001 to about 0.2.

4. The thermoelectric material as defined in claim 3 wherein: R is ytterbium; and A is an element other than ytterbium.

5. The thermoelectric material as defined in claim 3 wherein the filled skutterudite crystal structure has the formula Yb_{0.07}La_{0.05} Ba_{0.10}Co₄Sb₁₂.

6. The thermoelectric material as defined in claim 3 wherein the thermoelectric material has an average ZT of up to about 2.0 at a temperature of about 800K.

7. The thermoelectric material as defined in claim 3 wherein the rare earth element, the other rare earth element and the alkaline earth element independently have different phonon resonance frequencies.

8. A thermoelectric material comprising a filled skutterudite crystal structure having the formula R_{w}AₓB_{y}C_{z}M₄X₁₂, wherein:
R is a rare earth element;
A is a rare earth element other than R;
B is an alkaline earth element;
C is an alkali metal;
M is selected from the group consisting of cobalt, rhodium, and iridium;
X is selected from the group consisting of antimony, phosphorus, and arsenic; and
w, x, y, and z are a crystal structure filling fractions ranging from about 0.01 to about 0.2.

9. The thermoelectric material as defined in claim 8 wherein: R is ytterbium; and A is a rare earth element other than ytterbium

10. The thermoelectric material as defined in claim 8 wherein: A is lanthanum; B is barium; and C is selected from the group consisting of sodium and potassium.

11. The thermoelectric material as defined in claim 8 wherein the rare earth element, the other rare earth element, the alkaline earth element, and the alkali metal independently have different phonon resonance frequencies.

12. The thermoelectric material as defined in claim 8 wherein the filled skutterudite crystal structure has the formula Yb_{w}LaₓBa_{y}Na_{z}Co₄Sb₁₂, wherein w, x, y, and z ranges from about 0.01 to about 0.2.

13. The thermoelectric material as defined in claim 8 wherein the filled skutterudite crystal structure has the formula Yb_{w}LaₓBa_{y}K_{z}Co₄Sb₁₂, wherein w, x, y, and z ranges from about 0.01 to about 0.2.
